(19) United States
(12) Patent Application Publication
(10) Pub. No.: US 2017/0010303 A1
(43) Pub. Date: Jan. 12, 2017

(54) Adaptable Interface Assembly For Electronic Test And Control Systems

(71) Applicant: Advanced Integration, LLC, Columbus, OH (US)

(72) Inventors: Paul R. Salopek, II, Gahanna, OH (US); Michael P. Sheridan, Lancaster, OH (US); Christopher L. Reichle, Ray, OH (US); Joseph T. McGee, Lancaster, OH (US)

(73) Assignee: Advanced Integration, LLC, Columbus, OH (US)

(21) Appl. No.: 15/196,648

(22) Filed: Jun. 29, 2016

Related U.S. Application Data
(60) Provisional application No. 62/190,048, filed on Jul. 8, 2015.
(60) Provisional application No. 62/197,809, filed on Jul. 28, 2015.

(51) Int. Cl. G01R 1/04

(52) U.S. Cl. CPC G01R 1/0416; G01R 1/0433

(57) ABSTRACT

An electronic test and control system is provided. The electronic test and control system includes an enclosure configured to enclose one or more electronic boards and connective electrical wires. An adaptable interface assembly is attached to a face of the enclosure. The adaptable interface assembly includes a customized interface panel and one or more connectors connected to the customized interface panel. The adaptable interface assembly is configured to interface with application specific instruments and devices such as to eliminate the need for custom adapters positioned to interface with standard electronic test and control systems and application specific instruments and devices.

### RELATED APPLICATIONS

This application claims priority from pending U.S. Provisional Patent Application No. 62/190,048 filed Jul. 8, 2015 and U.S. Provisional Patent Application No. 62/197,809 filed Jul. 28, 2015, the disclosures of which are incorporated herein by reference in their entireties.

### BACKGROUND

Electronic test and control systems can be used for a variety of industrial purposes including control of machinery, measurement and monitoring functions, data acquisition, data communication, data processing and transfer functions, sensing functions and the like.

Electronic test and control systems can be utilized in various applications and in multiple industries, such as for example, automotive manufacturing plants, steel mills, oil fields, coal mines, medical facilities, defense installations and equipment, aerospace equipment, telecommunication applications, shipboard installations, power generation equipment, racing applications and off-road conditions.

In such environments, the electronic test and control systems can be subjected to harsh environments that impose difficult operating conditions (commonly called a “dirty environment”). For example, in certain situations, the electronic test and control systems can be subjected to chemicals, dust, grease, water, dirt, and grime.

In other environments, the electronic test and control systems can be sprayed with and/or immersed in fluids for varying periods of time. In still other environments, the electronic test and control systems can be subject to impact from rough handling and dropping. In certain instances, it is known to place the electronic test and control systems inside protective enclosures.

Given the wide variety of situations, environments and uses, it can be difficult, time-consuming and expensive to adapt electronic test and control systems to specific applications, instruments and devices. In certain instances, it is known to adapt “standard” electronic test and control systems with custom adapters positioned to interface with standard electronic test and control systems and application specific instruments and devices.

It would be advantageous if the electronic test and control systems could be improved.

### SUMMARY

It should be appreciated that this Summary is provided to introduce a selection of concepts in a simplified form, the concepts being further described below in the Detailed Description. This Summary is not intended to identify key features or essential features of this disclosure, nor is it intended to limit the scope of the adaptable interface assembly for electronic test and control systems.

The above objects as well as other objects not specifically enumerated are achieved by an electronic test and control system. The electronic test and control system includes an enclosure configured to enclose one or more electronic boards and connective electrical wires. An adaptable interface assembly is attached to a face of the enclosure. The adaptable interface assembly includes a customized interface panel and one or more connectors connected to the customized interface panel. The adaptable interface assembly is configured to interface with application specific instruments and devices such as to eliminate the need for custom adapters positioned to interface with standard electronic test and control systems and application specific instruments and devices.

There is also provided a method of determining the configuration of an adaptable interface assembly for use in an electronic test and control system. The method includes the steps of determining the application specific instruments and devices that will be connected to the electronic test and control system, determining the connectors that will be used by the application specific instruments and devices to connect to the electronic test and control system, programming and/or setting-up one or more electronic boards included in the electronic test and control system for application specific requirements, configuring the electronic boards with physical wiring points, determining the necessary connectors required to interface the physical wiring points of the electronic boards with the application specific instruments and devices, laying out the placement of the necessary connectors on a customized interface panel and connecting the connectors on the customized interface panel with the physical wiring points on the electronic boards.

Various objects and advantages of the adaptable interface for electronic test and control systems will become apparent to those skilled in the art from the following detailed description, when read in light of the accompanying drawings.

### BRIEF DESCRIPTION OF THE DRAWINGS

FIG. 1 is a perspective view of a first embodiment of an electronic test and control system incorporating an adaptable interface assembly.

FIG. 2 is a perspective view, partially cutaway, of the electronic test and control system of FIG. 1 illustrating an electronic board within an enclosure.

FIG. 3 is an exploded perspective view of the electronic test and control system of FIG. 1.

FIG. 4A is a front view, in elevation, of a first embodiment of an adaptable interface assembly of the electronic test and control system of FIG. 1.

FIG. 4B is a front view, in elevation, of a second embodiment of an adaptable interface assembly of the electronic test and control system of FIG. 1.

FIG. 4C is a front view, in elevation, of a third embodiment of an adaptable interface assembly of the electronic test and control system of FIG. 1.

FIG. 5 is a flow chart illustrating a method of determining the configuration of the adaptable interface assembly of the electronic test and control system of FIG. 1.

FIG. 6 is a perspective view of a second embodiment of an electronic test and control system incorporating an adaptable interface assembly.

FIG. 7A is a perspective view of a first embodiment of a thermocouple assembly for use in the electronic test and control system of FIG. 1.

FIG. 7B is an exploded perspective view of the thermocouple assembly of FIG. 7A.

FIG. 8A is an exploded perspective view of a first embodiment of an adaptive coupler for use in the electronic test and control system of FIG. 1.

FIG. 8B is an assembled perspective view of the adaptive coupler of FIG. 8A.

FIG. 9A is an exploded perspective view of a second embodiment of an adaptive coupler for use in the electronic test and control system of FIG. 1.

FIG. 9B is an assembled perspective view of the adaptive coupler of FIG. 9A.

### DETAILED DESCRIPTION

The adaptable interface assembly for electronic test and control systems will now be described with occasional reference to specific embodiments. The adaptable interface assembly for electronic test and control systems may, however, be embodied in different forms and should not be construed as limited to the embodiments set forth herein. Rather, these embodiments are provided so that this disclosure will be thorough and complete, and will fully convey the scope of the adaptable interface assembly for electronic test and control systems to those skilled in the art.

Unless otherwise defined, all technical and scientific terms used herein have the same meaning as commonly understood by one of ordinary skill in the art to which the adaptable interface assembly for electronic test and control systems belongs. The terminology used in the description of the adaptable interface assembly for electronic test and control systems herein is for describing particular embodiments only and is not intended to be limiting of the adaptable interface assembly for electronic test and control systems. As used in the description of the adaptable interface assembly for electronic test and control systems and the appended claims, the singular forms “a,” “an,” and “the” are intended to include the plural forms as well, unless the context clearly indicates otherwise.

Unless otherwise indicated, all numbers expressing quantities of dimensions such as length, width, height, and so forth as used in the specification and claims are to be understood as being modified in all instances by the term “about.” Accordingly, unless otherwise indicated, the numerical properties set forth in the specification and claims are approximations that may vary depending on the desired properties sought to be obtained in embodiments of the adaptable interface assembly for electronic test and control systems. Notwithstanding that the numerical ranges and parameters setting forth the broad scope of the adaptable interface assembly for electronic test and control systems are approximations, the numerical values set forth in the specific examples are reported as precisely as possible. Any numerical values, however, inherently contain certain errors necessarily resulting from error found in their respective measurements.

In accordance with illustrated embodiments, the description and figures disclose an adaptable interface assembly for electronic test and control systems and a method of using the adaptable interface assembly. Generally, the adaptable interface assembly includes a customized interface panel and a plurality of connectors configured to interface with application specific instruments and devices. The combination of the customized interface panel and the application-specific connectors eliminate the need for custom adapters positioned to interface with standard electronic test and control systems and application specific instruments and devices. In certain embodiments, the combination of the customized interface panel and the application-specific connectors can eliminate the need for rewiring of the cable hook-ups from the standard electronic test and control systems to the application specific instruments and devices.

The term “interface assembly”, as used herein, is defined to mean the combination of a panel and one or more connectors, instruments, indicators and/or fixtures associated with the panel. The term “panel”, as used herein, is defined to mean a structure upon which one or more connectors, instruments, indicators and/or fixtures are located. The term “adaptable”, as used herein, is defined to mean the interface assembly can be customized to interface with application specific instruments and devices.

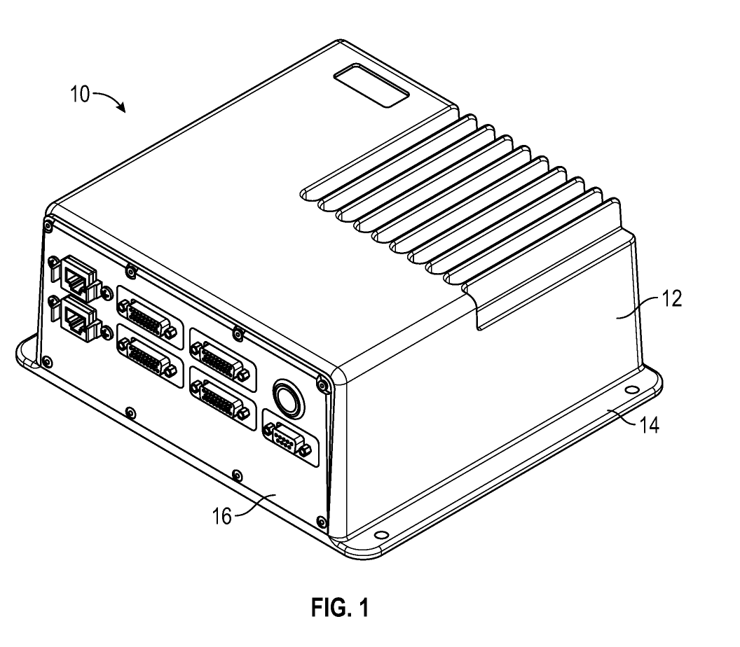

Referring now to FIGS. 1-3, one non-limiting embodiment of an electronic test and control system (hereafter “system”) is shown schematically at 10. The system 10 is configured to electrically interface with application specific testing and measurement instruments, control devices, data acquisition systems, monitoring applications, communications equipment and the like. The system 10 is further configured to provide control functions, measurement and monitoring functions, data acquisition, data communication, data processing and transfer functions, sensing functions and related input/output related electronic functions. The system 10 includes an enclosure 12 connected to a base 14 and an adaptable interface assembly 16 connected to the enclosure 12, one or more electronic boards 18 positioned within the enclosure 12, a plurality of electrical wires 20 connecting the adaptable interface assembly 16 to the one or more electronic boards 18 and an optional power supply (not shown).

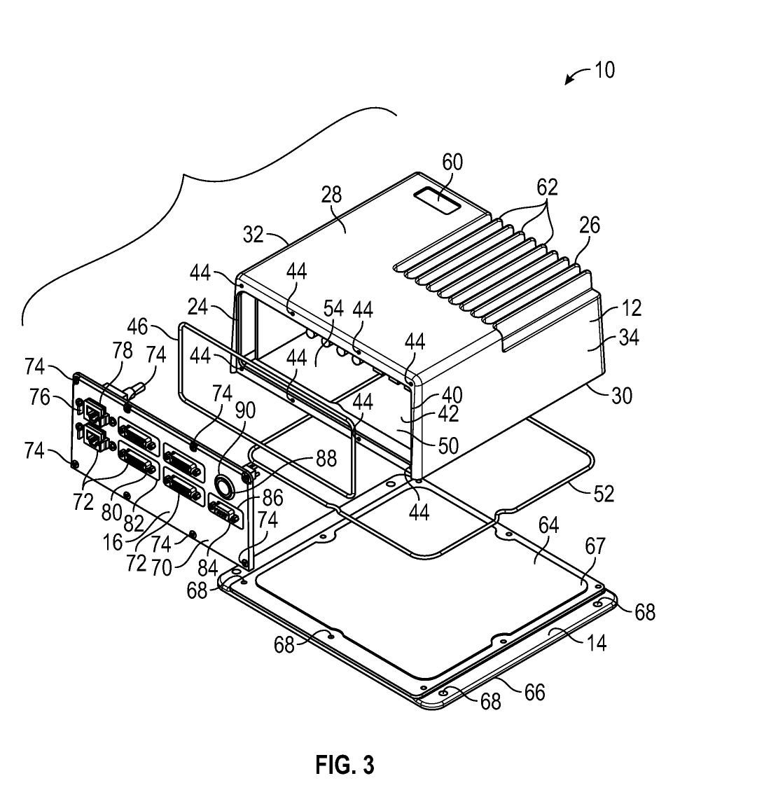

Referring again to FIGS. 1-3, the enclosure 12 is configured to support the adaptable interface assembly 16 and enclose the electronic boards 18, the plurality of electrical connectors 20 and the optional power supply. Referring now to FIG. 3, the enclosure 12 includes a front face 24, a rear face 26, a top face 28, a bottom face 30 and opposing side faces 32, 34.

Referring again to FIG. 3, the front face 24 of the enclosure 12 includes a circumferential channel 40, a cutout 42 and a plurality of threaded apertures 44. The circumferential channel 40 extends around the perimeter of the cutout 42 and is configured to receive a sealing member 46. The sealing member 46 is configured to provide a dust resistant and water resistant joint between the adaptable interface assembly 16 and the front face 24 of the enclosure 12. In the illustrated embodiment, the sealing member 46 is an O-ring having a rectangularly-shaped outline. However, in other embodiments, the sealing member 46 can be other structures, mechanisms and devices and can have other outline shapes sufficient to provide a dust resistant and water resistant joint between the adaptable interface assembly 16 and the front face 24 of the enclosure 12. The cutout 42 and the plurality of threaded apertures 44 of the front face will be discussed in more detail below.

Referring again to FIG. 3, the bottom face 30 of the enclosure 12 includes a circumferential channel (not shown), a cutout 50 and a plurality of threaded apertures. The circumferential channel 40 extends around the perimeter of the cutout 50 and is configured to receive a sealing member 52. The sealing member 52 is configured to provide a dust resistant and water resistant joint between the bottom face 30 of the enclosure 12 and the base 14. In the illustrated embodiment, the sealing member 52 is an O-ring having a substantially square-shaped outline. However, in other embodiments, the sealing member 46 can be other structures, mechanisms and devices and can other outline shapes sufficient to provide a dust resistant and water resistant joint between the bottom face 30 of the enclosure 12 and the base 14.

Referring again to FIG. 3, the cutout 50 in the bottom face 30 is configured to allow access to an interior cavity 54 defined by the faces 24, 26, 28, 30, 32 and 34 of the enclosure 12 in the event the base 14 is removed. The interior cavity 54 advantageously allows access to the electronic boards 18 and the electrical wires 20 contained within the system 10.

Referring again to FIG. 3, the top face 28 includes an optional window 60 and a plurality of heat sink fins 62. The window 60 is configured to provide visual inspection of portions of the electronic boards 18 positioned within the enclosure 12, such as the non-limiting example of an organic light-emitting diode display or (OLED). In the illustrated embodiment, the window 60 is formed from a protective material, such as for example, Gorilla® brand glass, manufactured by Corning Incorporated, headquartered in Corning, N.Y. However, in other embodiments. the window 60 can be made from other desired materials and can have any desired shape, size and configuration sufficient to provide visual inspection of portions of the electronic boards 18 positioned within the enclosure 12. However, it should be appreciated that the window 60 is optional and not required for operation of the system 10.

Referring again to FIG. 3, the heat sink fins 62 are positioned in close proximity to heat-generating portions (not shown) of the electronic boards 18. The heat sink fins 62 are configured to receive the heat generated by the heat-generating portions (not shown) of the electronic boards 18 and further configured to transfer the heat to the air, wherein the heat is dissipated away from the system 10. The heat sink fins 62 can have any desired shape, size and configuration sufficient to receive the heat generated by the heat-generating portions of the electronic boards 18 and transfer the heat to the air. However, it should be appreciated that the heat sink fins 62 are optional and not required for operation of the system 10.

Referring again to FIG. 3, the base 14 includes an upper major surface 64, a lower major surface 66 and a plurality of apertures 68 extending therethrough. The upper major surface 64 includes a raised surface 67. A perimeter of the raised surface 67 is configured to approximate the shape of the sealing member 52, such that in an assembled arrangement, the base 14 and the bottom face 30 of the enclosure 12 are substantially sealed against dust and water.

Referring again to FIG. 3, the apertures 68 are spaced apart around the perimeter of the base 14. Fasteners (not shown) are configured to extend through the apertures 68 and into threaded apertures (not shown) located in the bottom face 30 of the enclosure 12, thereby attaching the base 14 to the enclosure 12. In the illustrated embodiment, the fasteners are threaded screws, however, in other embodiments the base 14 can be attached to the enclosure 12 with other structures, mechanisms and devices, such as the non-limiting examples of clips and clamps.

Referring again to FIG. 3, the enclosure 12 is configured to enclose one or more electronic boards 18. The electronic boards 18 can be configured to provide various functions, including the non-limiting examples of control functions, measurement and monitoring functions, data acquisition, data communication, data processing and transfer functions, sensing functions, related input/output related electronic functions and the like. One non-limiting example of an electronic board 18 is a single-board computer with analog input/output and digital input/output, model sbRIO-9637, manufactured by National instruments Corporation, headquartered at 11500 Mopac Expressway, Austin, Texas, 78759. However, it should be appreciated that other electronic boards can be used.

Referring again to FIG. 3, the adaptable interlace assembly 16 is connected to the front face 24 of the enclosure 12. The adaptable interface assembly 16 includes a panel 70 and one or more receiving plugs, jacks, sockets, instruments, indicators and/or fixtures (collectively referred to as mating connectors) 72 supported by the panel 70. The panel 70 includes a plurality of apertures 74 extending in a spaced apart manner around the perimeter of the panel 70. Fasteners (not shown) are configured to extend through the apertures 74 and into the threaded apertures 44 located in the front face 24 of the enclosure 12, thereby attaching the adaptable interface assembly 16 to the enclosure 12. In the illustrated embodiment, the fasteners are threaded screws, however, in other embodiments the adaptable interface assembly 16 can be attached to the enclosure with other structures, mechanisms and devices, such as the non-limiting examples of clips and clamps.

Referring again to FIG. 3, the mating connectors 72 are configured to connect various portions of application specific instruments and devices (not shown) to the electronic board 18 via the electric wires 20. As can be appreciated, application specific instruments and devices can encompass a wide range of electrical plugs and connections, each requiring a mating connector 72. The mating connectors 72 can have different profiles, shapes and sizes, with each of the mating connectors 72 requiring an aperture in the panel 70 that approximates the cross-sectional profile of the mating connector 72. As a first example, connector 76 can be a standard ethernet jack (commonly referred to as a RJ45 jack). The connector 76 requires an aperture 78 having a substantially square cross-sectional profile in the panel 70. As another example, connector 80 can be a multi-pinned female external connector (commonly referred to as a high-density D-subminiature 26 position connector or HD DB-26), requiring an aperture 82 having a rectangular cross-sectional profile in the panel 70. As yet another example, connector 84 can be a female external connector (commonly referred to as a standard density d-subminiature 9 position connector or DB-9), requiring an aperture having a smaller, rectangular cross sectional profile in the panel 70. As a final non-limiting example, the panel 70 can include power on/power off switches and/or illuminated indicators, shown generally at 90. The switches and/or indicators can require an aperture 90 having a substantially circular profile.

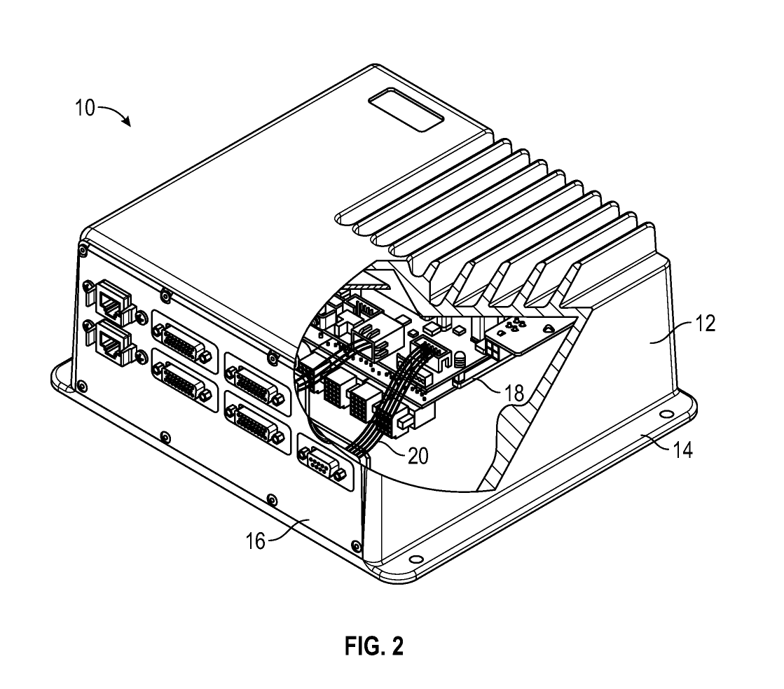

Referring again to FIGS. 2 and 3, the layout and placement of components on the electronic hoards 18 is a factor in determining the relative location and positioning^{,} of the mating connectors 72 on the panel 70. In certain instances, it is desirable to locate the mating connectors 72 in relatively close proximity to their associated components on the electronic boards 18 such that the electrical wires 18 are kept in good order,

Referring again to FIG. 3, given the wide range of electrical plugs and connections available for use with the system 10, and given the variability of the relative location and positioning of the mating connectors 72 on the panel 70, it is within the contemplation of the system 10 that the panel 70 is flexible to adapt to various circumstances without the use of interfacing adapters.

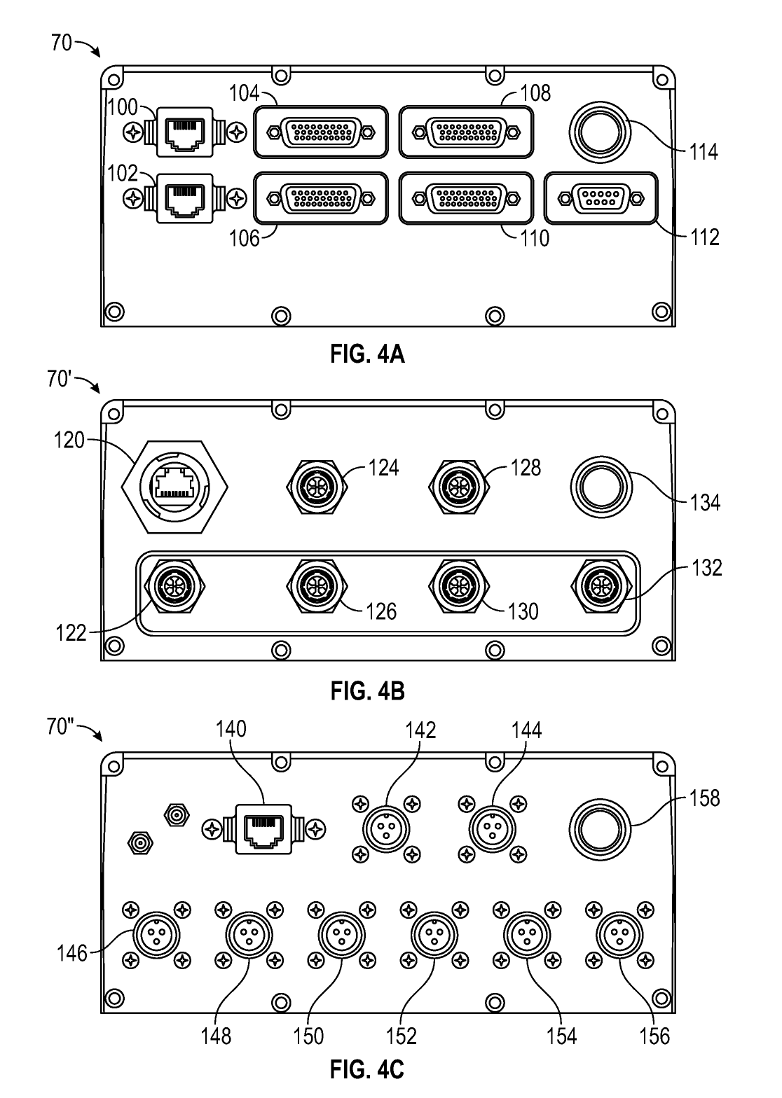

Referring now to FIGS. 4A-4C, non-limiting examples of different panel 70 configurations are illustrated, Referring now to FIG. 4A, panel 70 includes RJ45-style jacks 100 and 102, HD DB-26 style connectors 104, 106, 108 and 110, DB-9 style connector 112 and indicator 114. The jacks 100, 102 are positioned in a stacked arrangement at a far left side of the panel 70, the connectors 104, 106, 108 and 110 are positioned in stacked columns and centrally mounted on the panel 70 and the connector 112 and the indicator 114 are positioned in a stacked arrangement and mounted on the far right side of the panel 70.

Referring now to FIG. 4B, another configuration of a panel 70′ is illustrated, Panel 70′ includes an Ethernet cable jack 120, sockets 122, 124, 126, 128, 130 and 132 and indicator 134. The jack 120 and the socket 122 are positioned in a stacked arrangement at a far left side of the panel 70′, the connectors 124, 126, 128 and 130 are positioned in stacked columns and centrally mounted on the panel 70′ and the socket 132 and the indicator 134 are positioned in a stacked arrangement and mounted on the far right side of the panel 70′.

Referring now to FIG. 4C, another configuration of a panel 70″ is illustrated. Panel 70″ includes an Ethernet cable jack 140, sockets 142, 144, 146, 148, 150, 152, 154 and 156 and indicator 158. The jack 140, the sockets 142, 144 and the indicator 156 are positioned in an upper row of the panel 70″ and the sockets 146, 148, 150, 152, 154 and 156 are positioned in a lower row of the panel 70″.

Referring again to FIGS. 4A-4C, the interface panels 70, 70′, 70″ together with their respective plurality of connectors, are configured to interface with application specific instruments and devices. The combination of the customized interface panels, 70, 70′, 70″ and the application-specific connectors eliminate the need for custom adapters positioned to interface between standard electronic test and control systems and application specific instruments and devices.

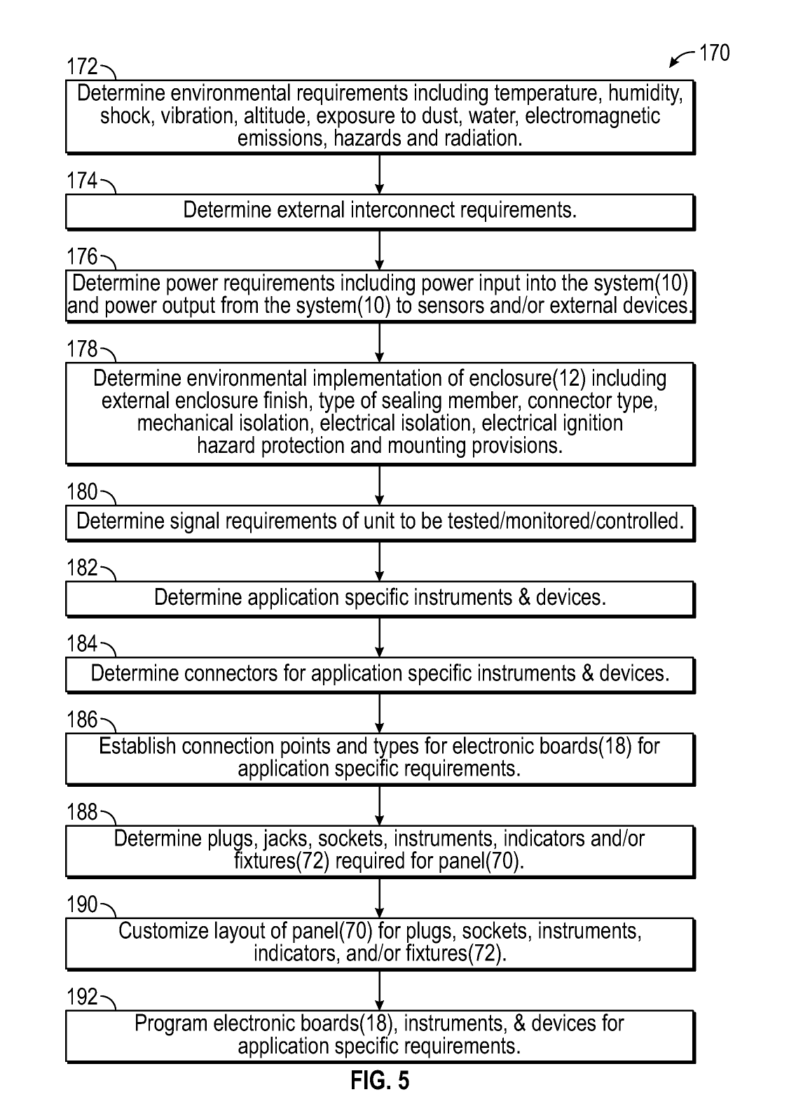

As discussed above, the interface panel 70 is adaptable to a wide variety of plugs, jacks, sockets, instruments, indicators and/or fixtures 72 and further adaptable to varying the layout of the plugs, jacks, sockets, instruments, indicators and/or fixtures 72 according to the requirements of the electronic board 18. Referring now to FIG. 5, the method of determining the configuration of the panel 70 is illustrated generally as 170. In an initial step 172, the environmental requirements of the system 10 are determined. The environments requirements include considerations for environmental temperature, humidity, shock, vibration, altitude, exposure to dust, water, electromagnetic emissions, hazards and radiation. In a next step 174, the external interconnect requirements are determined. This includes considerations for user required or preferred connectors, water proofing and/or dust proofing requirements, requirements for ruggedness including vibration, shock, impact and the like, price, keying, color coding, ergonomics, labeling and grouping. In a next step 176, the power requirements are determined, including the power input requirements into the system and power output requirements from the system to sensors and/or external devices. In a next step 178, the environmental implementation of the enclosure 12 is determined, including considerations for external enclosure finish, type of sealing member, connector type, mechanical isolation, electrical isolation, electrical ignition hazard protection and mounting provisions. Next in step 180, the signal requirements of the unit to be tested/monitored/controlled are determined. In a next step 182, the application specific instruments and devices are determined. This is simply an inventory of the structures, mechanisms and devices that will be connected to the system 10. Next, as shown in step 184, the connectors for the application specific instruments and devices are determined. This step provides a list, including quantities, of specific connectors that will engage plugs, jacks, sockets, instruments, indicators and/or fixtures 72 located on the panel 70.

Referring again to FIG. 5 in a next step 186, the electronic boards 18 are configured with physical wiring points, such that the application specific information and/or signals received by the plugs, jacks, sockets, instruments, indicators and/or fixtures 72 can be conveyed to the appropriate components on the electronic boards 18 by the electric wires 20. In a next step 188, the necessary plugs, jacks, sockets, instruments, indicators and/or fixtures 72 required for the panel 70 to interface to the application specific instruments and devices without the use of adapters positioned between the system 10 and the application specific instruments and devices are determined.

Referring again to FIG. 5 in a next step 190, the layout of the panel 70 is configured taking into consideration the necessary plugs, jacks, sockets, instruments, indicators and/or fixtures and further in consideration of the desire to closely locate the necessary plugs, jacks, sockets, instruments, indicators and/or fixtures to their associated components on the electronic boards 18.

In a final step 192, the one or more electronic boards 18 are programmed and/or setup for the application specific requirements. The programming and/or setup step 192 provides that the electronic board 18 is configured for application specific functions such as control functions, measurement and monitoring functions, data acquisition, data communication, data processing and transfer functions, sensing functions, related input/output related electronic functions and the like.

Referring again to FIG. 3, in certain embodiments the system 10 is configured for dust resistant, immersion resistant and rugged environmental conditions. As discussed above, the sealing member 46 is configured to provide a dust resistant and water resistant joint between the adaptable interface assembly 16 and the front face 24 of the enclosure 12. In a similar manner, the sealing member 52 is configured to provide a dust resistant and water resistant joint between the bottom face 30 of the enclosure 12 and the base 14. At the same time, the connectors 72 attached to the panel 70 can be equipped with dust resistant and water resistant fittings, such that cutout 42 in the front face 24 of the enclosure 12 and the cutout 50 in the bottom face 30 of the enclosure 12 are substantially sealed.

In certain embodiments, the sealing of the system 10 is sufficient for the system 10 to pass the following test standards: IEC 60529 Water Immersion Test (also known as International Protection Code 67, defining the ability of equipment to be protected from dust and further defining the ability of equipment to be protected from the effects of immersion in water to depth between 15 cm and 1 meter), IEC 60068-2-1 & 60068-2-2 Hot/Cold Test (defining the suitability of equipment to function under conditions or high heat or low cold conditions) and IEC 60068-2-56 Humidity Test (defining the suitability of equipment to function under conditions of high humidity).

In certain embodiments, the system 10 is sufficiently rugged for the system 10 to pass the following test standards: IEC 60068-2-27 Shock Resistance Test (defining the ability of equipment to withstand specified severities of non-repetitive or repetitive shocks), IEC 60068-2-64 Random Vibration Test (defining the ability of equipment to withstand random vibrations) and IEC 60068-2-6 Sinusoidal Vibration Test (defining the ability of equipment to withstand sinusoidal vibrations).

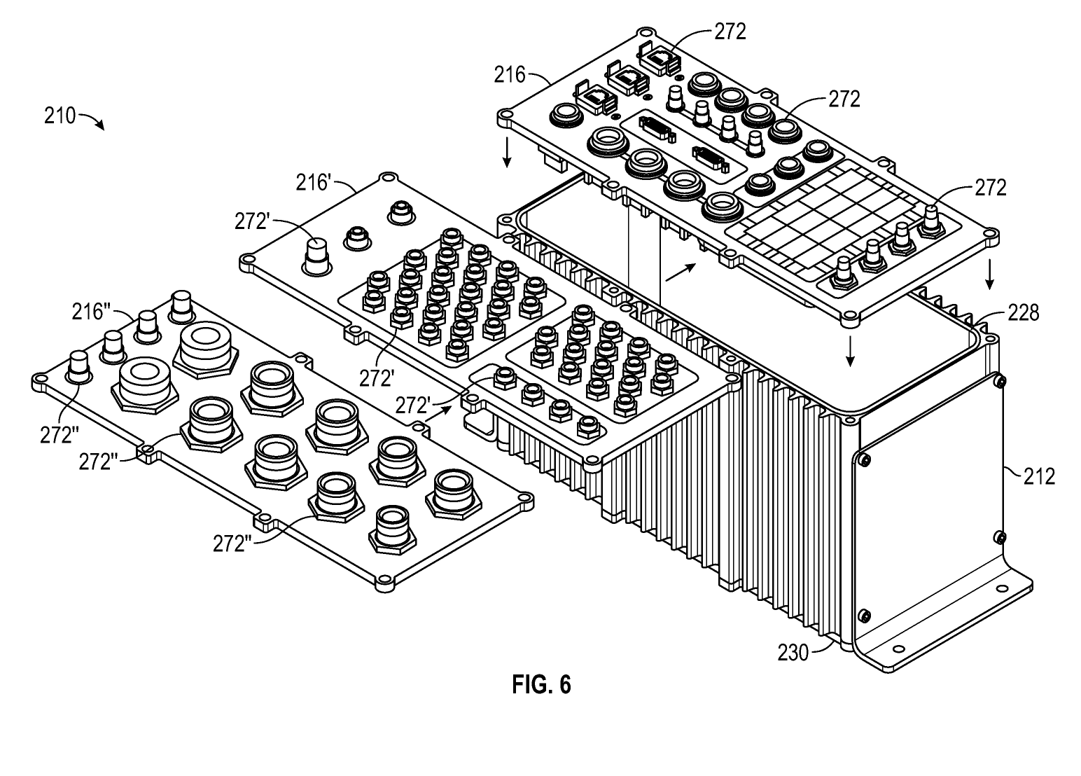

While the system 10 described above and shown in FIGS. 1, 2 and 3 provides for attachment of the adaptable interface assembly 16 to the front face 24 of an enclosure 12, it should be appreciated that in other embodiments, the system can be configured differently. Referring now to FIG. 6, a second embodiment of a system 216 is illustrated. In this embodiment, the system 210 includes an enclosure 212 having an adaptable interface assembly 216 mounted to a top face 228 of the enclosure 212. The system 210 is further configured such as to rest on the bottom face 230 of the enclosure 212, the face opposite the adaptable interface assembly 216. In the illustrated embodiment, the enclosure 212 is the same as, or similar to, the enclosure 12 described above and illustrated in FIGS. 1-3. However, in other embodiments, the enclosure 212 can be different from the enclosure 12.

Referring again to FIG. 6, the system 210 is configured for panel 216 and alternate panels 216′, 216″, with each of the panels 216, 216′ and 216″ having a plurality of application specific plugs, jacks, sockets, instruments, indicators and/or fixtures (collectively the connectors 272, 272′, 272″). In the illustrated embodiment, the panels 216, 216′, 216″ and the connectors 272, 272′, 272″ are the same as, or similar to, the panel 16 and the connectors 72 described above and illustrated in FIGS. 1-3. However, in other embodiments, the panels 216, 216′, 216″ and the connectors 272, 272′, 272″ can be different from the panel 16 and the connectors 72.

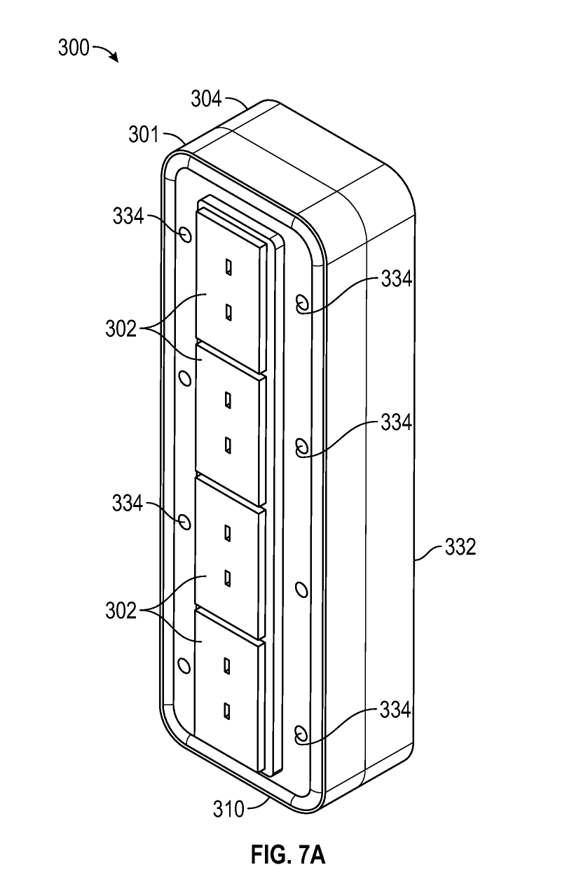

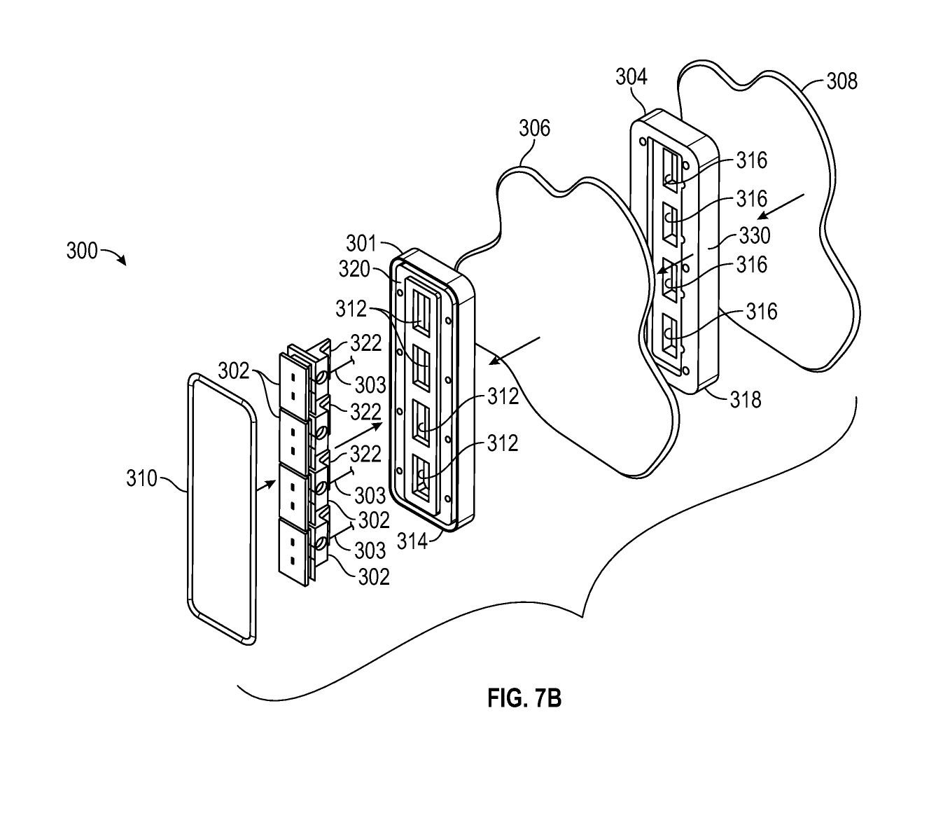

Referring now to FIG. 3 and as described above, the connectors 72 can include a variety of devices including plugs, jacks, sockets, instruments, indicators and/or fixtures. Referring now to FIGS. 7A and 7B, another type of fixture, referred to as a thermocouple assembly, is illustrated generally at 300. Generally, the thermocouple assembly 300 provides a plurality of inexpensive, commercially available thermocouple connectors arranged in a substantially dust and water resistant assembly. The thermocouple assembly 300 includes a first framework 301, a plurality of thermocouple connectors 302, a second framework 304, sealant material 306, electrical potting material 308 and a sealing member 310.

Referring now FIG. 7B, the first framework 301 includes a plurality of apertures 312, each configured to receive a thermocouple connector 302. The apertures 312 have a cross-sectional shape and size the closely approximates the cross-sectional shape and size of the thermocouple connectors 302, such as to form a close fit therebetween. In the illustrated embodiment, the apertures 312 have a rectangular cross-sectional shape approximating to the rectangular cross-sectional shape of the thermocouple connectors 302. Alternatively, in other embodiments, the apertures 312 have other cross-sectional shapes sufficient to form a close fit with thermocouple connectors 302.

Referring again to FIG. 7B, the first framework 301 includes an outer rim 314 extending around the perimeter of the apertures 312. The outer rim 314 will be discussed in more detail below.

Referring again FIG. 7B, the second framework 304 includes a plurality of apertures 314, each configured to receive a thermocouple connector 302. In a manner similar to the apertures 312, the apertures 316 have a cross-sectional shape and size the closely approximates the cross-sectional shape and size of the thermocouple connectors 302

Referring again to FIG. 7B, the second framework 304 includes an outer rim 318 extending around the perimeter of the apertures 316. Referring now to FIG. 7A, in an assembled arrangement, the outer rims 314, 318 of the first and second frameworks 301, 304 are configured to align with each other such that the corresponding apertures 312, 316 in the frameworks 301, 304 also align.

Referring again to FIG. 7B, the thermocouple connectors 302 are mini thermocouple connectors equipped with blade-style contacts. The thermocouple connectors 302 are typically readily available and inexpensive. One non-limiting example of the thermocouple connectors 302 is manufactured by Omega Engineering, headquartered in Stamford, New York. However, it should be appreciated that in other embodiments, other thermocouple connectors 302 can be used.

Referring again to FIG. 7B, the thermocouple assembly 300 is assembled as described in the following steps. First, electrical wires (shown schematically at 303) are connected to the thermocouple connectors 302. The electrical wires 303 are configured for connection to one of the one or more electronic boards 18. Next, the thermocouple connectors 302 are positioned in the first framework 301 such that the thermocouple connectors 302 are seated against a front face 320 of the first framework 301, the rear portions 322 of the thermocouple connectors 302 extend in a direction toward the second framework 304 and the electrical wires 303 extend through the apertures 312. Next, the second framework is brought into contact with the first framework 301, such that the outer rims 314, 318 contact and align with each. When arranged in this manner, the rear portions 322 of the thermocouple connectors 302 and the electrical wires 303 extend through the apertures 316 in the second framework 304.

Referring again to FIG. 7B, in a next step a sealant material 306 is inserted between the first and second frameworks 301, 304. The sealant material 306 is configured to fill available spaces between the frameworks, 301, 304 and the thermocouple connectors 302. The sealant material 306 is configured to seal the thermocouple assembly 300 such that the thermocouple assembly 300 is substantially dust and water resistant. One non-limiting example of the sealant material 306 is Loctite 59375 Superflex Black RTV, Silicone Adhesive, manufactured by Henkel Corporation, headquartered in Dusseldorf, Germany. However, it should be appreciated that in other embodiments, other sealant materials 306, sufficient to fill available spaces between the frameworks, 301, 304 and the thermocouple connectors 302 and seal the thermocouple assembly 300 such that the thermocouple assembly 300 is substantially dust and water resistant can be used.

In certain embodiments, optionally the second framework 304 can include a plurality of ports (not shown) configured to guide the sealant material 306 into the spaces between the frameworks, 301, 304 and the thermocouple connectors 302. The ports can have any shape, size and configuration sufficient to guide the sealant material 306 into the spaces between the frameworks, 301, 304 and the thermocouple connectors 302.

Referring again to FIG. 7B, in a next step, an electrical potting material 306 is applied to a rear face 330 of the second framework 304. The electrical potting material 306 is configured to fill spaces between the second framework 304 and the thermocouple connectors 302, thereby sealing a rear portion 332 of the thermocouple assembly 300. One non-limiting example of the sealant material 306 is Kona 870FTLV-DP, manufactured by Resin Technology Group, headquartered South Easton, Massachusetts. However, it should be appreciated that in other embodiments, other electrical potting materials 306 can be used.

Referring again to FIG. 7B, in a next step, a sealing member 310 is positioned between the thermocouple assembly 300 and the panel 70 and configured to provide a dust resistant and water resistant joint between the thermocouple assembly 300 and the panel 70 of the adaptable interface assembly 16. In the illustrated embodiment, the sealing member 310 is an O-ring having a rectangularly-shaped outline. However, in other embodiments, the sealing member 310 can be other structures, mechanisms and devices and can have other outline shapes sufficient to provide a dust resistant and water resistant joint between the thermocouple assembly 300 and the panel 70 of the adaptable interface assembly 16.

Referring again to FIG. 7A in a final step, the thermocouple assembly 300 is attached to the panel 70 with fasteners (not shown) configured to engage threaded apertures 334 located in the first framework 301. In certain embodiments, the fasteners can be screws, however, in other embodiments, the thermocouple assembly 300 can be attached to the panel 70 with other structures, mechanisms and devices, including the non-limiting examples of clips and clamps.

While the embodiment of the thermocouple assembly 300 illustrated in FIGS. 7A and 7B show a quantity of four thermocouple connectors 302, it should be appreciated that in other embodiments, more or less than four thermocouple connectors 302 can be used. In the event that more or less than four thermocouple connectors 302 are used, it is within the contemplation of the thermocouple assembly 300 that the first and second frameworks can be revised to include the same number of apertures as thermocouple connectors.

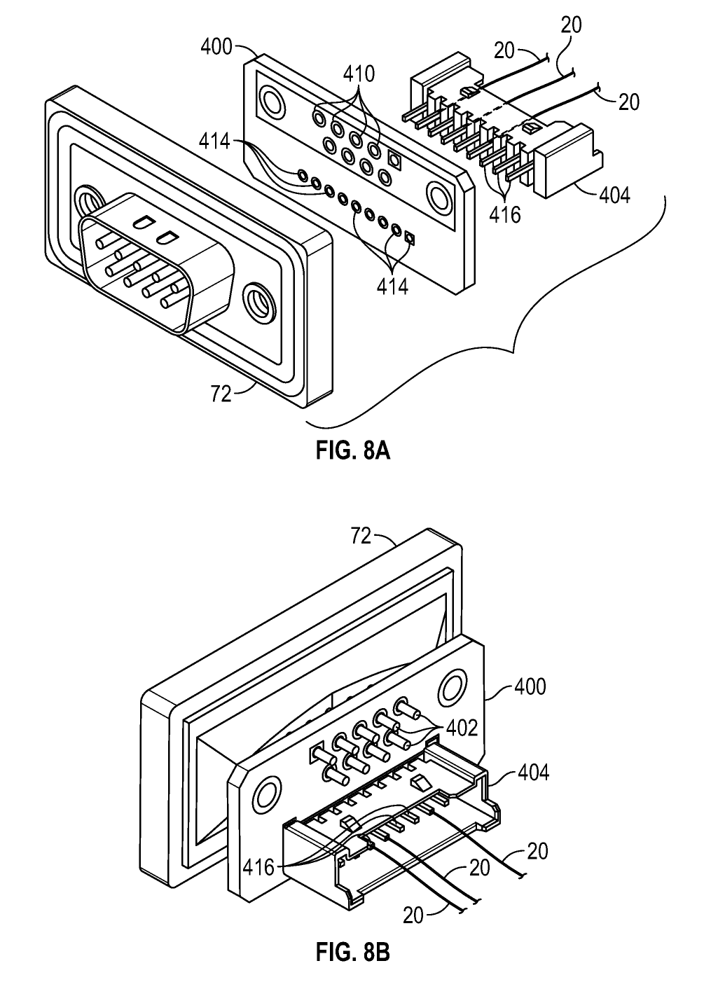

Referring again to FIG. 2 as described above, the electrical wires 20 are configured to connect the connectors 72 located on the panel 70 to the one or more electronic boards 18. However, in other embodiments, the connectors 72 can be electrically connected to the electrical wires 20 with other structures. Referring now to FIGS. 8A and 8B, in certain embodiments, the connectors 72 can be equipped with one or more coupler boards 400. The coupler board 400 is configured to engage pins 402 extending from the connectors 72 and electrically couple the pins 402 with standard sockets and/or plugs 404.

Referring again to FIG. 8A, the coupler board 400 includes a first plurality of apertures 410 arranged to connect to and electrically engage the pins 402 extending from the connectors 72. Engagement of the first plurality of apertures 410 with the pins 402 is accomplished by a frictional fit therebetween. In an installed arrangement, the pins 402 can extend through the apertures 410 as shown in FIG. 8B.

Referring again to FIG. 8A, the coupler board 400 includes a plurality of internal tracts (not shown) configured to electrically connect the apertures 410 to a second plurality of apertures 414. The apertures 414 are configured to receive pins 416 extending from the plug 404. The pins 416 of the plug 404 are configured to receive the electrical wires 20 extending from the electrical boards 18. Accordingly, the pins 402 of the connectors 72 are connected to the electrical wires 20 extending from the electronic boards 18, via the apertures 410, the internal tracts within the coupler board 400, the apertures 414 and via the pins 416 of the plug 404. In this manner, the electrical wires 20 extending from the electrical boards 18 are wired to the pins 416 of the plug 404 and not to the pins 402 of the connectors 72.

Use of the coupler board 400 advantageously provides several benefits, although all benefits may not be available in all embodiments. First, the use of the coupler board provides flexibility in the design of the system 10, while maintaining commonality with the interfacing components such as the connectors 72 and the electronic boards 18. Second, the use of the coupler board 400 provides continuity and integrity of the signals provided by the connectors 72 to the electronic boards 18. Third, the use of the coupler board 400 provides a connection strength, thereby facilitating the IP-67 rating discussed above. Fourth, use of the coupler board 400 allows for great variety of connectors 72 to be used while the plug 404 within the system 10 can remain substantially the same from connector 72 to connector 72, or if not the exact same (by pin count) at least the same type/series of connector. Fifth, with the plug 404 remaining constant, the process for assembling the electrical components within the system 10 becomes much more reliable and repeatable (e.g. using the same tooling, wire, terminal, etc. every time reduces variability). As a sixth benefit, use of the coupler board 400 provides a positive, repeatable contact with the pins 402 of the connector 72, thereby avoiding methods of physically soldering wires 20 to the conventional “solder cup” style connectors 72. The conventional methods, while simple, are not very repeatable, even with a very experienced technician. There can be a risk of a cold solder joint or heat induced failure of the connector 72 which can lead to degradation of the connector 72 and a possible leakage point.

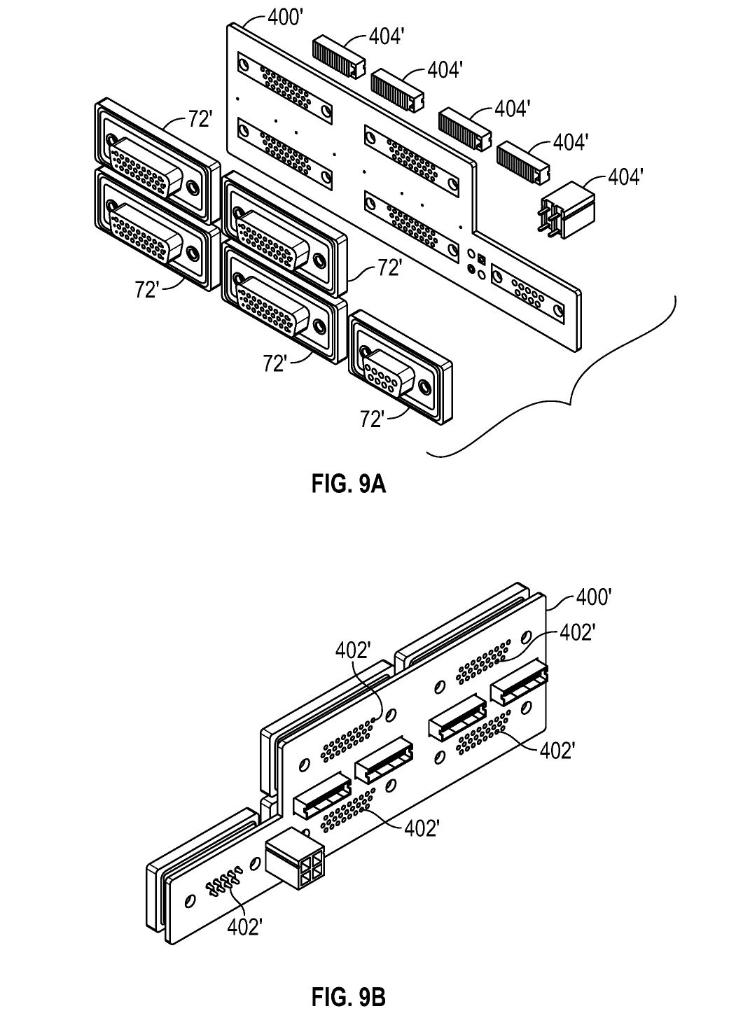

While the coupler board 400 shown in FIGS. 8A and 8B is configured for a lone connector 72, it should be appreciated that in other embodiments, a lone coupler board can be configured for more than one connector 72. Referring now to FIGS. 9A and 9B, an alternate coupler board 400′ is illustrated. The coupler board 400′ is configured to engage pins 402′ extending from the connectors 72′ and further configured to electrically couple the pins 402′ with standard sockets and/or plugs 404′. In the illustrated embodiment, the coupler board 400′ is the same as, or similar to, the coupler board 400 described above and shown in FIGS. 8A and 8B. In other embodiments, the coupler board 400′ can be different from the coupler board 400.

The principle and mode of operation of the adaptable interface assembly for electronic test and control systems has been described in certain embodiments. However, it should be noted that the adaptable interface assembly for electronic test and control systems may be practiced otherwise than as specifically illustrated and described without departing from its scope. what is claimed is:

1. An electronic test and control system comprising:
an enclosure configured to enclose one or more electronic boards and connective electrical wires; and
an adaptable interface assembly attached to a face of the enclosure, the adaptable interface assembly including a customized interface panel and one or more connectors connected to the customized interface panel;
wherein the adaptable interface assembly is configured to interface with application specific instruments and devices such as to eliminate the need for custom adapters positioned to interface with standard electronic test and control systems and application specific instruments and devices.

2. The electronic test and control system of claim 1, wherein the connectors located on the customized interface panel include one or more from the list of plugs, jacks, sockets, instruments, and/or fixtures.

3. The electronic test and control system of claim 1, wherein the customized interface panel includes an illuminated indicator.

4. The electronic test and control system of claim 1, wherein the customized interface panel includes a different assortment of connectors from a customized interface panel configured for a different application specific instrument or device.

5. The electronic test and control system of claim 1, wherein the one or more electronic boards are configured for application specific functions including one or more from the list of control functions, measurement and monitoring functions, data acquisition, data communication, data processing and transfer functions, sensing functions and related input/output related electronic functions.

6. The electronic test and control system of claim 1, wherein the connectors located on the customized interface panel are connected to physical wiring points on the one or more electronic boards by electric wires.

7. The electronic test and control system of claim 1, wherein the electronic test and control system is dust resistant and water resistant to achieve Ingress Protection Code 67.

8. The electronic test and control system of claim 1, wherein the one of the connectors located on the customized interface panel is a thermocouple assembly.

9. The electronic test and control system of claim 8, wherein the thermocouple assembly includes a first framework connected to second framework and a plurality of thermocouple connectors positioned therebetween.

10. The electronic test and control system of claim 1, wherein a coupler board is positioned between the one or more connectors and the one or more electrical boards, and wherein the coupler board is configured to engage pins extending from the connectors and electrically couple the pins with standard sockets and/or plugs.

11. A method of determining the configuration of an adaptable interface assembly for use in an electronic test and control system, the method comprising the steps of:
determining the application specific instruments and devices that will be connected to the electronic test and control system;
determining the connectors that will be used by the application specific instruments and devices to connect to the electronic test and control system;
programming and/or setting-up one or more electronic boards included in the electronic test and control system for application specific requirements;
configuring the electronic boards with physical wiring points;
determining the necessary connectors required to interface the physical wiring points of the electronic boards with the application specific instruments and devices;
laying out the placement of the necessary connectors on a customized interface panel; and
connecting the connectors on the customized interface panel with the physical wiring points on the electronic boards.

12. The method of claim 11, wherein the connectors located on the customized interface panel include one or more from the list of plugs, jacks, sockets, instruments, indicators and/or fixtures.

13. The method of claim 11, wherein the programming and/or setup step of the one or more electronic board includes programming and/or set-up for application specific functions including one or more from the list of control functions, measurement and monitoring functions, data acquisition, data communication, data processing and transfer functions, sensing functions and related input/output related electronic functions.

14. The method of claim 11, wherein the connectors located on the customized interface panel are connected to the physical wiring points on the one or more electronic boards by electric wires.

15. The method of claim 11, wherein the electronic test and control system is connected to the application specific instruments and devices without the use of adapters positioned between the electronic test and control system and the application specific instruments and devices.

16. The method of claim 11, including the step of placing the necessary connectors on a customized interface panel in close proximity with the associated components on the one or more electronic boards.

17. The method of claim 11, wherein the electronic test and control system is dust resistant and water resistant to achieve Ingress Protection Code 67.

18. The method of claim 11, wherein the one of the connectors located on the customized interface panel is a thermocouple assembly.

19. The method of claim 18, wherein the thermocouple assembly includes a first framework connected to second framework and a plurality of thermocouple connectors positioned therebetween.

20. The method of claim 11, wherein a coupler board is positioned between the one or more connectors and the one or more electrical boards, and wherein the coupler board is configured to engage pins extending from the connectors and electrically couple the pins with standard sockets and/or plugs.
